(19) United States
(12) Patent Application Publication
(10) Pub. No.: US 2012/0112366 A1
(43) Pub. Date: May 10, 2012

(54) Power Electronic Module

(75) Inventor: Jean-Christophe Charles Nicolas Crebier, Bevenais (FR)

(73) Assignee: CENTRE NATIONAL DE LA RECHERCHE SCIENTIFIQUE, Paris (FR)

(21) Appl. No.: 13/382,775

(22) PCT Filed: Jul. 8, 2010
(86) PCT No.: PCT/FR10/00503

§ 371 Date: Jan. 23, 2012

(30) Foreign Application Priority Data
Jul. 8, 2009 (FR) 09 03366

(51) Int. Cl. H01L 25/07

(52) U.S. Cl. 257/777; 257/E25.014

(57) ABSTRACT

The invention relates to a power electronic module comprising a plurality of bridge arms mounted in parallel and a plurality of output terminals (BS) connected to the middle points of said bridge arms, characterized in that it comprises at least two semi-conductor chips (P₁, P₂), each of the chips including in a single-block form a plurality of semi-conductor switches (T) implemented according to a vertical technology and having active and voltage holding areas electrically insulated from each other, each switch of a chip being connected to a respective switch of another chip so as to form a bride arm. The invention also relates to a power electronic module that comprises a stack of four semi-conductor chips and five semi-conducting layers arranged alternatively so as to form a switching cell having a coaxial structure.

The invention relates to a power electronic module comprising a plurality of bridge arms connected in parallel. The invention also relates to a power electronic module comprising a switching cell having a coaxial structure.

The bridge arm is a basic configuration that is extremely important in power electronics. It is formed by two switches (diodes, transistors, thyristors, etc.) connected in series with a contact point between the two. Using two or more bridge arms, it is possible to construct a wide variety of power electronic circuits, such as choppers, voltage or current inverters, controlled rectifiers, etc.

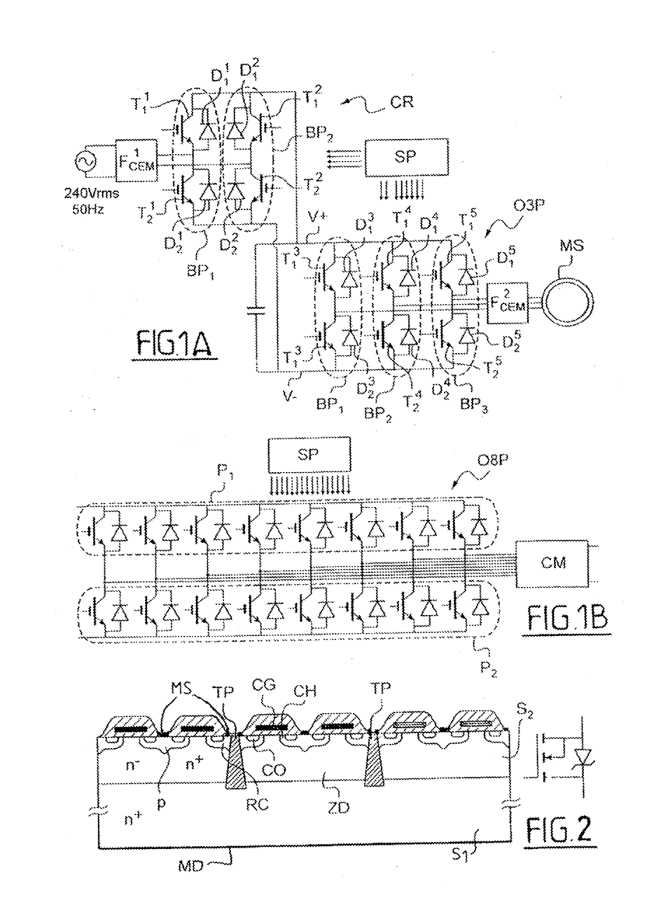

FIG. 1A shows, by way of example, a circuit allowing the single-phase AC voltage at 50 Hz, 240 V (rms) of the electrical power distribution system to be converted into a three-phase voltage of variable frequency. This circuit comprises—in addition to the low-voltage control electronics—five bridge arms: two forming a controlled rectifier and three others forming a three-phase inverter.

Sometimes, an even higher number of bridge arms is needed. In particular, document FR 2 888 396 describes a magnetic coupler using a multi-phase power supply, for example with eight phases (FIG. 1B).

For applications at low switched power (up to around 300 W), the monolithic integration of circuits consisting of a number of bridge arms is made possible by the use of diodes or transistors with horizontal structures. At higher power, however, the use of devices with vertical structures becomes necessary. These devices completely traverse the semiconductor material wafer within which they are formed; for example, in the case of a field-effect transistor, the source and gate electrodes are located on the “front” face of the substrate and the drain electrode on its “back” face. When several devices with a vertical structure are formed on the same substrate, their active and voltage blocking regions are in mutual electrical contact: these devices cannot therefore operate independently from one another. It is therefore necessary to separate them after fabrication, in order to use them as discrete components. For general information on power components with a vertical structure, reference may be made to the document: Application Note AN-1084 “Power MOSFET Basics”, published by the International Rectifier Society, author Vrej Barkhordarian, and also to “Application Training Guide—Device Cross Sections”, http://www.irf.com/technical-info/guide/device.html.

Thus, the circuit in FIG. 1A comprises twenty discrete power components (ten transistors and as many antiparallel connected diodes), plus ten low-power integrated circuits carrying out the close control of the switches, there being thirty chips in total. For an eight-phase inverter designed to power a magnetic coupler, such as that shown in FIG. 1B, forty-eight chips are needed. It will be understood that the complexity of such a circuit, the cost of the interconnections and the associated reliability problems can quickly become prohibitive.

The article by P. Igic and al. “Technology for Power Integrated Circuits with Multiple Vertical Power Devices”, Proceedings of the 18th International Symposium on Power Semiconductor Devices & ICs, 4-8 Jun. 2006, Naples, Italy, describes a fabrication technique for integrated circuits comprising a plurality of power components with a vertical structure insulated from one another. The implementation of this technique is very complex, and hence costly, a fact which offsets, at least in part, the advantages gained by the integration. The same is true for the techniques described by documents U.S. Pat. No. 3,689,992 and U.S. Pat. No. 5,496,760.

Documents US 2008/0135932 and US 2008/0042164 disclose microelectronics chips integrating several active devices with a vertical structure insulated from one another by trenches filled with a dielectric material traversing the entire thickness of the substrate of the chip. Consequently, only the dielectric trenches together with (in the case of document US 2008/0135932) a thin layer of dielectric deposited on the back face of the chip preserve the structural integrity of the latter. The end result is very fragile chips that are difficult to manipulate.

The main aim of the invention is to overcome the aforementioned drawbacks of the prior art by making simpler, and improving the performance and reliability of, the fabrication and the implementation of power circuits composed of a plurality of bridge arms connected in parallel. The invention is also aimed at improving the thermal and electromagnetic performances of these circuits and, more generally, of power switching cells.

The inventor has realized that it is actually possible to simplify the structure of a power module comprising a plurality of bridge arms connected in parallel significantly by using a “dual-chip” structure. In such a structure, all the switches forming the “top part” of the module (in other words included between the positive voltage supply line and the mid-points of the bridge arms) undergo monolithic integration into a first semiconductor chip, furrows or trenches providing the insulation of their active and voltage blocking regions. Similarly, all the switches forming the “bottom part” of the module (included between the mid-points and the negative voltage supply line) are integrated into a second chip.

Employing two chips, respectively integrating the “top part” and the “bottom part” of the module, instead of a single chip, relaxes some of the constraints on the isolation of devices with a vertical structure. The reason for this is that the devices on the same chip possess one terminal (drain/collector or source/emitter) at the same potential. These devices do not therefore have to be completely separated from one another, a fact which simplifies the fabrication of the insulating or isolating structures.

It goes without saying that it would still be within the scope of the invention if several pairs of chips (“dual-chips”) were used to form a power module.

This basic structure may be broken down into several variants which exhibit additional advantages, notably in terms of reliability, heat dissipation and electromagnetic compatibility—essential considerations in power electronics.

As will be explained in greater detail hereinafter, the fabrication of a “dual-chip” structure according to the invention requires significant technical difficulties to be overcome.

More precisely, one subject of the invention is therefore a power electronic module comprising a plurality of bridge arms connected in parallel and a plurality of output terminals connected to the mid-points of said bridge arms, comprising at least two semiconductor chips, each of said chips monolithically integrating a plurality of solid-state switches fabricated using vertical technology whose active and voltage blocking regions are electrically isolated from one another, each switch of one chip being connected to a respective switch of another chip in such a manner as to form one said bridge arm, characterized in that each of said chips comprises a conducting element (degenerated semiconductor or thick metal layer) extending over one of its faces and ensuring both its structural integrity and an electrical connection between all the switches of the chip. The fragility of certain aforementioned modules of the prior art is thus remedied.

Another object of the invention is a power electronic module comprising a plurality of bridge arms connected in parallel and a plurality of output terminals connected to the mid-points of said bridge arms, comprising at least two semiconductor chips, each of said chips monolithically integrating a plurality of solid-state switches fabricated using vertical technology whose active and voltage blocking regions are electrically isolated from one another, each switch of one chip being connected to a respective switch of another chip in such a manner as to form one said bridge arm, characterized in that said switches exhibit symmetrical voltage blocking, subject to which said bridge arms are able to operate as current inverter arms.

Yet another subject of the invention is a power electronic module comprising a stack of four semiconductor chips and of five conducting layers arranged alternately, two of said semiconductor chips integrating with vertical technology at least one respective controlled switch, whereas each of the two other semiconductor chips integrate, also using vertical technology, at least one respective diode, said controlled switches and said diodes being configured in a functionally symmetrical manner with respect to a central conducting layer and in such a manner as to form a switching cell.

Advantageous features of various embodiments of the invention form the object of the dependant claims.

Other features, details and advantages of the invention will become apparent upon reading the description presented with reference to the appended drawings given by way of example and which respectively show:

FIGS. 1A and 1B, two simplified circuit diagrams of power circuits known from the prior art;

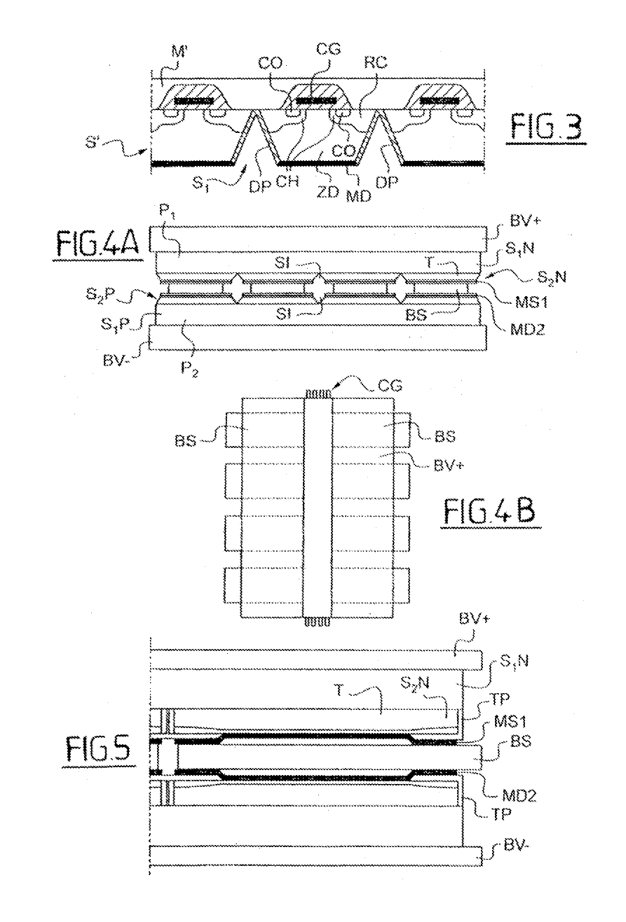

FIGS. 2 and 3, two embodiments of a chip integrating a plurality of solid-state switches being suitable for the implementation of the invention;

FIGS. 4A and 4B, a cross-sectional and a plan view, respectively, of a module with a three-dimensional structure according to one variant of the invention;

FIG. 5, a cross-sectional view of a module with a three-dimensional structure formed by pressed assembly according to another variant of the invention;

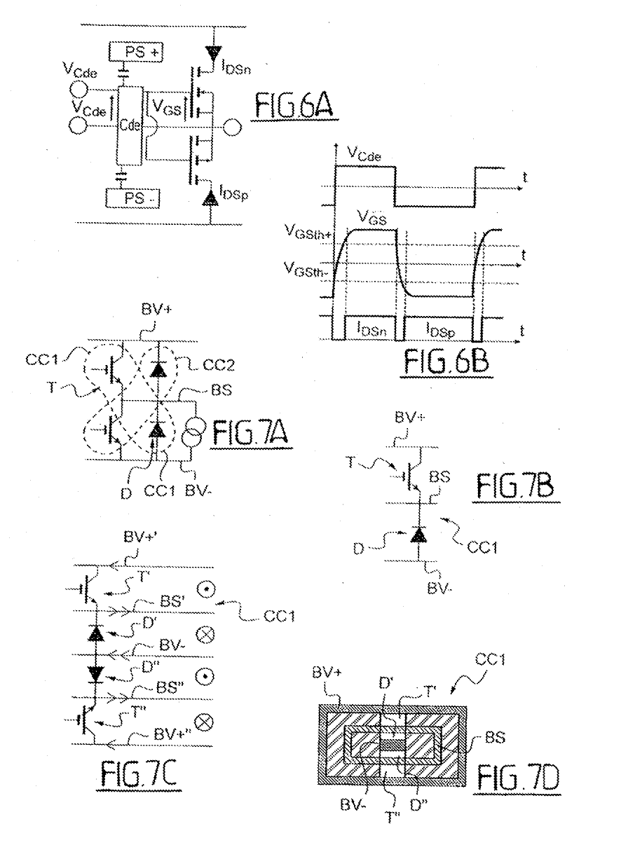

FIGS. 6A and 6B, a circuit diagram and a timing diagram, respectively, illustrating the control of a bridge arm fabricated using complementary technology according to one embodiment of the invention;

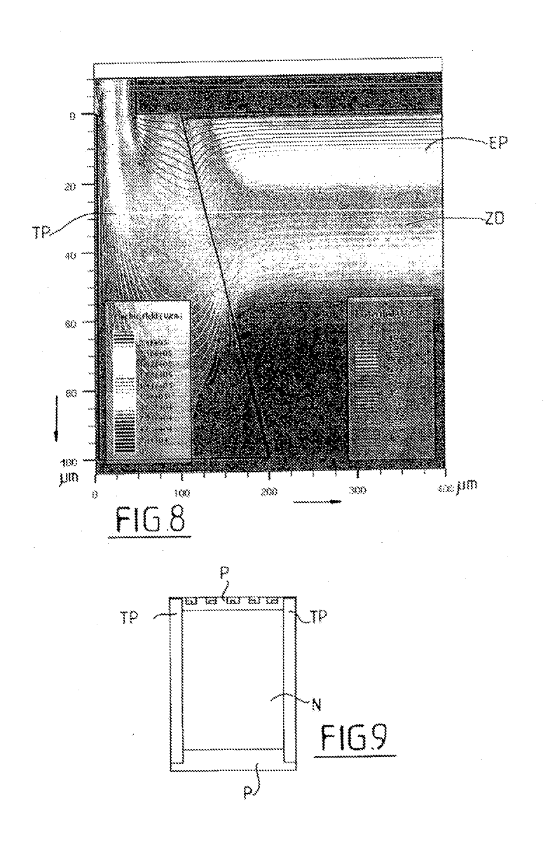

FIGS. 7A to 7D, the principle of a switching cell with a “coaxial” structure according to a first embodiment of this concept;

FIG. 8, the equipotential surfaces in a vertical voltage termination;

FIG. 9, a detailed view of the vertical voltage termination of a component with symmetrical voltage blocking;

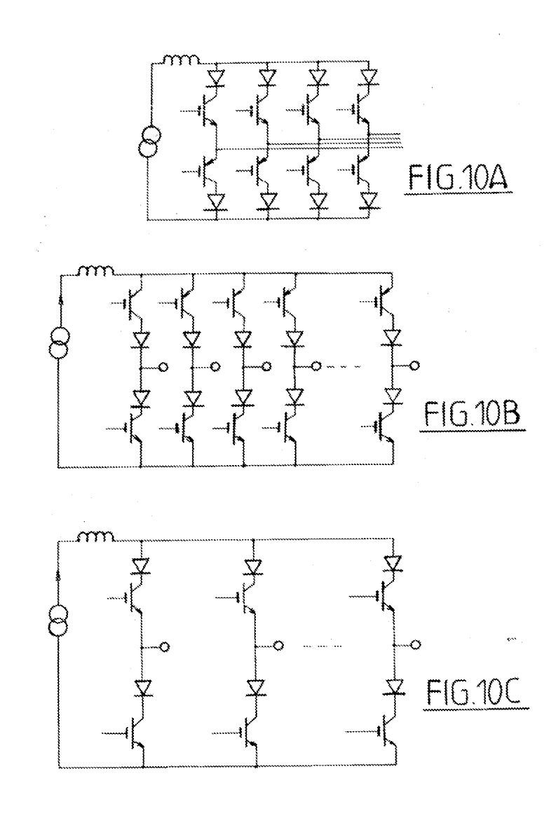

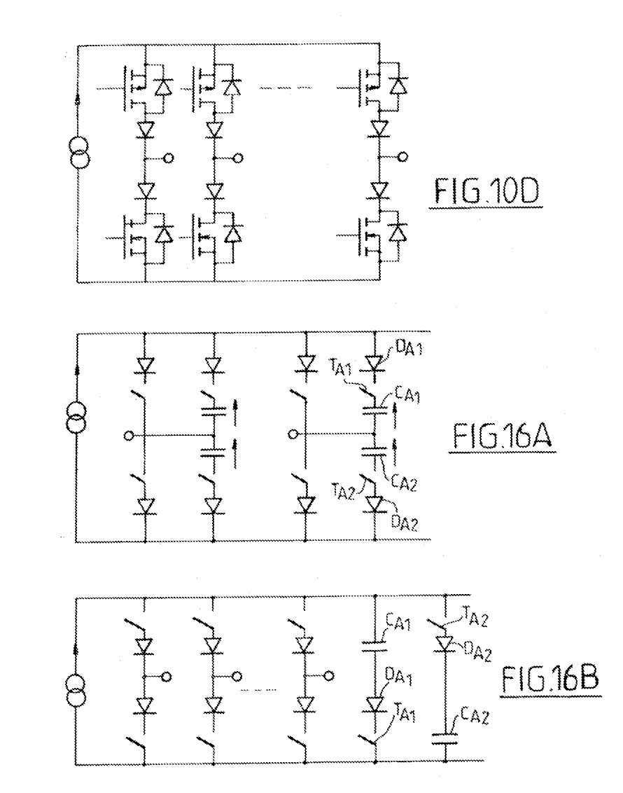

FIGS. 10A to 10C, the circuit diagrams of three variants of a multiphase current switch according to respective embodiments of the invention;

FIGS. 11A and 11B, an inverter arm in a “coaxial” structure according to a second embodiment of this concept;

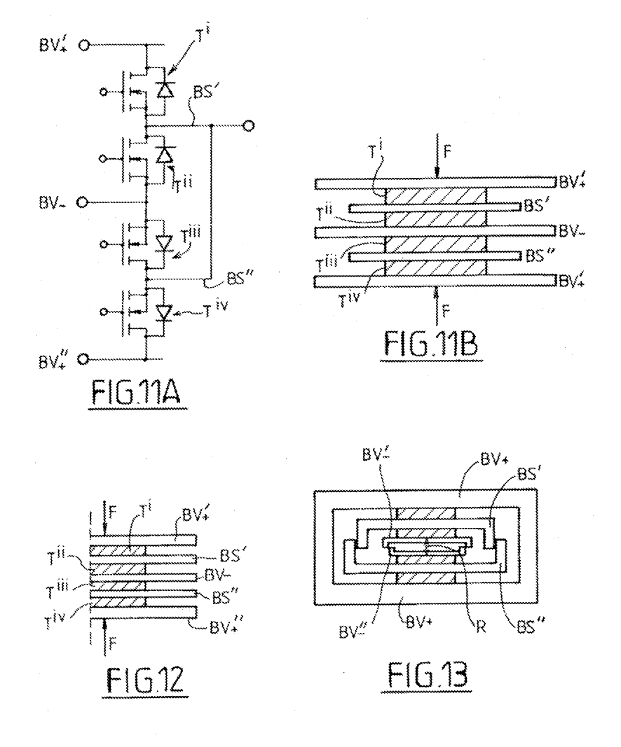

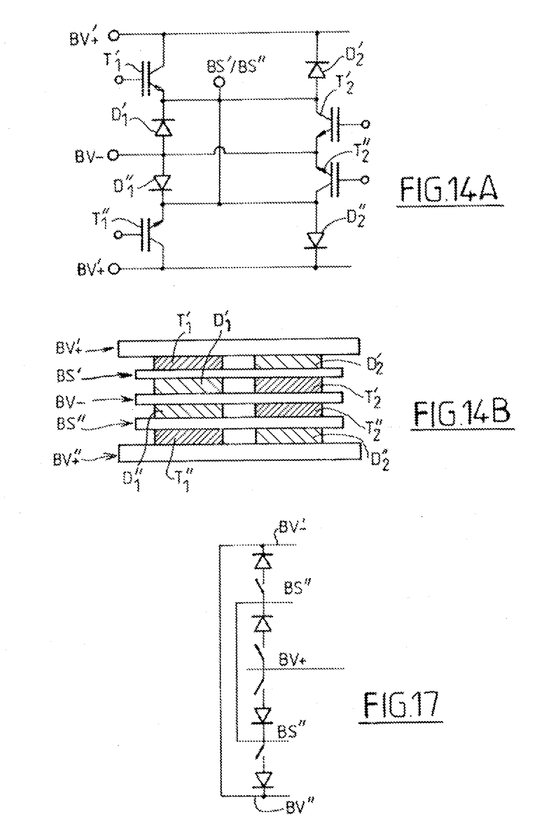

FIGS. 12 and 13, construction details of “coaxial” structures according to FIGS. 7A-7D or 11A-11B;

FIGS. 14A and 14B, an inverter arm assembled from two coaxial switching cells of the type in FIG. 7A;

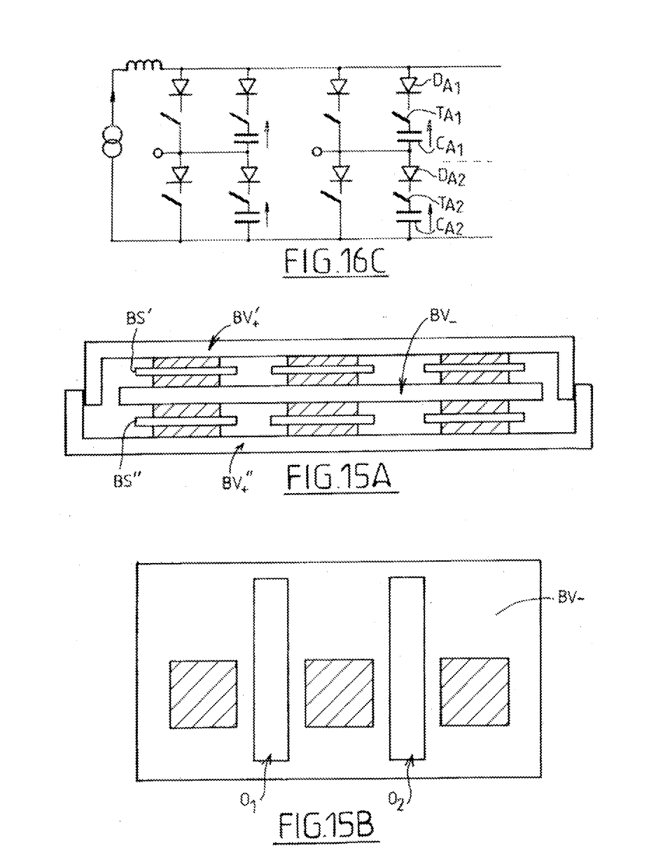

FIGS. 15A and 15B, a three-phase inverter assembled from three coaxial switching cells of the type in FIGS. 11A and 11B;

FIGS. 16A, 16B, 16B-1, 16B-2, 16B-3 and 16C, “self-powering” circuits for the close controls of the current switches in FIGS. 10A to 10C; and

FIG. 17, the circuit diagram of a bidirectional voltage switching cell that can be integrated using “coaxial” technology.

FIGS. 1A and 1B, to which reference has already been made, show simplified circuit diagrams of two power electronic circuits, known per se and capable of being implemented according to the invention.

The circuit in FIG. 1A is composed of a controlled rectifier CR and a three-phase inverter O3P. The rectifier CR converts the AC voltage from the electrical distribution system (240 V rms, 50 Hz single-phase) into a DC voltage at 400 V; the inverter O3P converts this rms voltage into a sinusoidal three-phase voltage with variable frequency capable of powering, for example, a synchronous motor MS.

The rectifier CR is essentially formed by two bridge arms BP₁, BP₂ connected in parallel. Each bridge arm is composed of two solid-state switches connected in series; in this instance, each switch is formed by one IGBT (isolated gate bipolar transistor) T₁¹, T₂¹, T₁², T₂² and one antiparallel freewheeling diode D₁¹, D ₂¹, D₁², D₂². Both the transistors and the diodes have vertical structures and are implemented in a discrete form.

The inverter O3P itself is formed by three bridge arms BP₃-BP₅ whose structure is substantially the same as that of the rectifier.

The transistors T₁¹-T₂⁵ are controlled by integrated close-control circuits, not shown, connected to their gates. These close-control circuits in turn receive control signals from an external control system SP.

Filters F_{CEM}¹ and F_{CEM}² are respectively provided between the power distribution system and the rectifier, and between the inverter and the synchronous motor, in order to filter out the high-frequency spurious signals generated by the operation of the switches.

As explained above, fabricating the circuit in FIG. 1A by conventional hybrid integration techniques implements at least 30 individual chips: ten IGBT, ten high-speed diodes and ten integrated close-control circuits.

The circuit in FIG. 1B comprises eight bridge arms connected in parallel to form an eight-phase inverter O8P designed to power a magnetic coupler CM. For a circuit of this type, comprising a larger number of bridge arms (eight in the figure; two more may be added for a single-phase controlled rectifier, or even three for a three-phase rectifier), the advantage afforded by the present invention is even greater.

As explained above, the invention is based on the monolithic co-integration within a first semiconductor chip P₁ of all the switches forming the “top part” of the device (in other words included between the positive supply line V+ and the output terminals—connection to the magnetic coupler) and the monolithic co-integration within a second semiconductor chip P₂ of all the switches forming its “bottom part” (included between the output terminals and the negative supply line V−). This subdivision is illustrated symbolically in FIG. 1B by dotted lines. Conventionally, in power electronics, the diodes can be co-integrated with the corresponding transistors, or even form an integral part of it (“structural diodes” or “body diodes”).

It can be noted, in FIG. 1B, that all the devices on the same chip have first terminals connected together to a common potential and second “free” terminals connected to the output terminals of the device. In the case of the first chip P₁, these “first terminals” are the collectors of the IGBT and the cathodes of the freewheeling diodes, connected to the positive supply line V+, whereas the emitters of the IGBT and the anodes of the diodes constitute the “free terminals”. In the second chip P₂, the reverse is true.

This observation is essential, because it avoids the various devices on each chip having to be completely isolated: only the second terminals, the active regions and the voltage blocking regions of these devices must effectively be isolated. In contrast, the first terminals can be connected by a common conducting region. This notably allows the fabrication, assembly and implementation processes for these chips to be simplified.

FIG. 2 shows a cross-sectional view of one portion of a semiconductor chip according to a first embodiment of the invention.

This chip comprises a first substrate S₁ fabricated from a semiconductor material (typically silicon) that is degenerated, in other words with a high concentration of dopants—in this case, electron donors—which provide it with a conductivity that is virtually metallic. The thickness of the first substrate S₁ is typically around 500 μm so as to give it a sufficient mechanical resistance during the fabrication process. A metallization layer MD is deposited on one face, referred to as the “back face”, of this substrate. The reference MS indicates the source metallizations.

On the “front face” of the substrate S₁, opposite to said back face, an epitaxial layer S₂ of semiconductor material is deposited, within which the power electronic devices will be formed. This layer has a doping of the same type as that of the first substrate, but of lower concentration (n−). The thickness of this layer S₂ is typically around 50 μm or less.

Using totally conventional photolithography processes on the “front face”, electronic devices such as N-channel MOSFETs (symbol on the right of the figure) are fabricated within the epitaxial layer S₂. For example, in the case illustrated in FIG. 2, “body” regions RC with p doping and contact regions CO with n+ doping are formed on the surface of said layer. The body and contact regions bound the channel regions CH, above which gate electrodes CG are formed from polysilicon insulated by layers of an oxide insulator. Metallizations MS are deposited on top of this oxide and contact regions CO. In a known manner, the metallizations MS form source contact areas for the various MOSFET cells (or emitter contacts, if the devices are IGBTs), whereas the metallization layer on the back face MD forms a common drain contact (or common collector, for the IGBT).

The channel regions CH and the “body” regions RC form the “active” regions of the devices. The deepest part of the layer S₂, extending up to the interface with the substrate S₁, constitutes the diffusion or voltage blocking region ZD. In a conventional manner in power electronics, each transistor can be formed from several “elementary cells”, each of which comprises a “body” region RC with p doping and one or two contact regions CO with n+ doping.

The active and voltage blocking regions of the devices thus formed are isolated from one another by trenches TP, fabricated by deep etching by means of beams of reactive ions, filled with dielectric (generally, but not necessarily, SiO₂). These trenches do not go into the substrate S₁, or at least only for a fraction of its depth. Consequently, the drains of all the transistors of the chip are electrically connected together and held at the same potential. As can be verified in FIGS. 1A and 1B, this does not represent a drawback when it is desired to integrate only the devices of the “top part” of a set of parallel bridge arms. On the other hand, this simplifies the chip fabrication process considerably and, in particular, the integration of a plurality of independent transistors, by permitting the monolithic co-integration in a simple manner of several multi-potential power switches. If it had been desired to achieve a complete isolation of the devices, it would have been necessary to etch trenches also traversing the substrate S₁, or else use an insulating substrate S₁ and bring the drain contacts onto the front face.

The trenches TP play a dual role. On the one hand, as was discussed above, they allow the isolation of the various devices that must be able to switch independently from one other; on the other hand, they provide the termination of the equipotentials at the edges of the voltage blocking region. This second function is important, and deserves to be dwelt upon further. The voltage blocking region ZD is the part of the device in which most of the voltage blocking between the drain and the source (in the case of a field-effect transistor) occurs. Within this region, the equipotential surfaces are approximately planar. The device is dimensioned so as to avoid breakdown events occurring within the voltage blocking region; however, breakdown is always a risk along the lateral edges of the device, where there are surface defects. For this reason, it is necessary to bound the voltage blocking region with trenches having smooth sidewalls, filled with a sufficiently rigid dielectric material (notably SiO₂, by chemical vapor-phase deposition). On this subject, see the article by Philippe Leturcq, “Power semiconductor voltage blocking”, D 3 104-1, Engineering techniques, Electrical Engineering paper.

Simulations show that the blocking voltage of the devices is maximized when the trenches are slightly flared, such that the sidewall of the region ZD forms an angle of around 100° with the interface S₁/S₂. Under these conditions, as illustrated in FIG. 8, the equipotentials EP exiting from the region ZD are inflected downward (toward said interface S₁/S₂) before bending back upward toward the front surface of the chip.

It is interesting to note that the use of vertical terminations (deep trenches) also allows the monolithic integration of devices with symmetrical voltage blocking such as IGBTs, triacs and certain thyristors. Indeed, these devices have two P-N junctions, one on the front face and the other on the back face, which are in principle capable of holding the voltage.

In reality, in conventional discrete devices, the division of the component significantly degrades the blocking voltage of the rear junction. Techniques for the fabrication of discrete devices with bidirectional voltage blocking are described in the articles:
“A new peripheral planar structure allowing symmetrical voltage blocking”, O. Causse and al., Proceeding of the 1999 International Semiconductor Conference CAS'99, 5-9 Oct. 1999, Volume 1, Pages 59-62.
“A New Isolation Technique for Reverse Blocking IGBT with Ion Implantation and Laser Annealing to Tapered Chip Edge Sidewalls”, Proceedings of the 18th International Symposium on Power Semiconductor Devices & ICs, 4-8 Jun. 2006, Naples, Italy; and
“On-state and Transient Characterization of a Monolithic MBS (Mos Bidirectional Switch)”, A. Dartigues and al. Conference Records of the 2001 IEEE Industry Application Conference—36th IAS Annual Meeting, 30 Sep.-4 Oct. 2001, Volume 1, Pages 648-652.

These techniques are fairly complex to implement. However, the use of deep trenches filled with a dielectric allows a termination on the back face of just as good quality as that on the front face (see FIG. 9) to be obtained in a simple and inexpensive manner.

As will be explained in detail hereinbelow, the trenches may be formed during or at the end of the chip fabrication process, and filled with dielectric after this process is finished.

The monolithic integration of components with symmetrical voltage blocking notably allows circuits to be obtained, according to the “dual-chip” concept of the invention, which, up till now, have been very rarely employed. By way of example, the current switch, also referred to as “current inverter”, may be mentioned, three variant embodiments of which are illustrated in FIGS. 10A-10C, which is the twin structure of the voltage inverter (FIGS. 1A and 1B), necessitating a bidirectional voltage blocking (and unidirectional current blocking), until now difficult to achieve. The problems specific to the integration of inverters or current switches will be described in detail hereinbelow.

Until now, only the monolithic integration of the devices forming the “upper half” of a set of parallel bridge arms has been considered. The integration of the elements forming the “lower half” of the module poses an additional difficulty. Indeed, in this case, it is the sources (or emitters, in the case of IGBTs) which must be held at a common potential, whereas the drains (or collectors) must form the “free” terminals. This is not possible in the case of a chip of the type shown in FIG. 2.

A solution to this problem consists in using p-type substrates S₁, S₂, and hence in fabricating p-channel transistors. At first sight, this solution seems on the face of it to have to be rejected: indeed, it is well known that p-type power devices possess electrical characteristics that are much less favorable than their n-type counterparts: higher control losses, in conduction and in switching, together with a lower power density. In practice, their use is avoided whenever possible. However, as will be shown later, a power module according to the invention possesses characteristics that are globally superior to those of a device using discrete components, despite the use of p-type devices.

A second embodiment of the invention, illustrated by means of FIG. 3, allows the use of devices of the same type (n or, if exceptionally it were to be advantageous in practice, p). In this embodiment, the devices with a vertical structure are integrated into a uniform substrate S′, having a thickness of the order of 50-500 μm, and preferably of the order of 50-300 μm, obtained by thinning of a thicker substrate. Like in the case of FIG. 2, each transistor can comprise several elementary cells, but only one has been shown for the sake of simplifying the figure.

After the fabrication of said devices, but prior to the formation of the isolating trenches, a thick metallization layer M′ is deposited on the back face or on the front face of the substrate. The case is for example considered of an n-type substrate (the most advantageous in practice) into which MOSFETs are integrated; if the metallization layer M′ is deposited on the back face, a common drain structure is obtained equivalent to that in FIG. 2, in which the substrate S₁ of degenerated semiconductor has been replaced by metal; in contrast, if the metallization layer M′ is deposited on the front face—case shown in FIG. 3—a common source and “free” drain structure is obtained. In this latter case, openings in the metallization layer M′ need to be provided in order to allow independent access to the gate electrodes CG.

In both cases, the isolating trenches are formed later.

In the example shown in FIG. 3, the isolation of the devices is not obtained by vertical, narrow and deep trenches, as in the case of FIG. 2, but by “V-shaped” furrows (referenced SI), formed by wet etching and whose walls are coated with a passivation dielectric DP such as SIPOS (semi-insulating polycrystalline silicon). The result is a structure of the “mesa” type, conventional (see the aforementioned article by Philippe Leturcq) in discrete devices. Advantageously, at the time of encapsulation, the furrows can be filled with a dielectric gel, for example silicone.

As a variant, it would have been possible to use an isolation by vertical trenches in the framework of the device in FIG. 3, or conversely to use an isolation by “V-shaped” furrows in the device in FIG. 2.

In any case, the isolating trenches or furrows may advantageously be formed after the diffusion and metallization operations required for the fabrication of the devices per se. This allows access to virtually all the existing technologies for the implementation of the invention.

After the separate fabrication of the two chips P₁ and P₂ monolithically integrating the switches of the top part and of the bottom part of the module, respectively, they must be electrically and mechanically connected together in such a manner as to form the pairs of switches constituting each bridge arm. The most advantageous way of proceeding consists in producing a three-dimensional stack as shown in FIGS. 4A and 4B.

The power module shown in these figures, in a cross-sectional and in a plan view, respectively, is obtained by superposing two chips each integrating a plurality of switches, in such a manner that the “free terminals” of the switches of the first chip are disposed facing the corresponding free terminals of the switches of the second chip so as to form bridge arms.

From top to bottom, the stack in FIG. 4A comprises:
A conducting element BV+ designed to be connected to a positive voltage power supply rail;
A first semiconductor N-type chip P₁, comprising a first degenerated substrate S₁N, in electrical contact with the element BV+ and an epitaxial layer S₂N within which N-MOSFET transistors with a vertical structure (referenced T) are formed. As explained with reference to FIG. 2, the drains of these transistors are held at a common potential by the first degenerated substrate S₁ N and the conducting element BV+. The active and voltage blocking regions of the transistors are separated from one another by isolating furrows SI, forming terminations of the “mesa” type.
A source metallization layer MS1, rendered discontinuous by the isolating furrows.
Electrical connecting elements BS, generally metal, forming the output terminals of the module.
A metallization layer MD2, also rendered discontinuous by the isolating furrows, for the interconnection of the drains of the P-MOSFET transistors forming the bottom part of the set of bridge arms.
A second semiconductor chip P₂, of the P type, comprising an epitaxial layer S₂P in which P-MOSFET transistors with a vertical structure are formed and a first degenerated substrate S₁P. An N-MOSFET transistor from the first chip and a P-MOSFET transistor from the second chip form one bridge arm, whose mid-point coincides with an output terminal BS. The sources of the P-MOSFET are connected to the corresponding output terminals via respective metallization layers MD2.
A conducting element BV− in electrical contact with the degenerated substrate S₁P, and hence with the drains of the P-MOSFET, designed to be connected to a negative voltage power supply rail.

The assembly can be carried out by brazing or clamping.

FIG. 4B shows a plan view of the module. The gate contacts CG of the transistors can also be seen in the figure.

Conventionally, the diodes form an integral part of the transistors with a vertical structure.

It should be understood that FIGS. 4A and 4B are highly simplified and are only intended to represent the basic concepts of the invention schematically. Numerous variants and improvements may be envisioned. For example, the control electronics for the transistors may be integrated into the power module, in a monolithic manner (on one of the chips or both) or hybrid manner (on separate chips, interconnected to the power chips). The sources of the transistors can have an interleaved structure, so as to increase the surface area in a manner known per se. Furthermore, the “switches” can be MOSFETs, as in the example, but equally may be IGBTs, bipolar junction transistors (BJT), thyristors or diodes. It is also possible to fabricate bridge arms composed of different devices: for example, a transistor in the top part and a diode in the bottom part.

FIGS. 4A and 4B relate to the case of a module with a complementary structure (P and N) with chips based on an epitaxial structure. It goes without saying that the same type of assembly may be produced with chips based on a thinned substrate, of the complementary type or otherwise. The voltage terminations may just as easily be of the “mesa” type or of the vertical trench type.

The three-dimensional assembly in FIGS. 4A and 4B constitutes a preferred embodiment of the invention for reasons that will be detailed hereinafter. However, it may also be envisioned to dispose the two chips side by side and to interconnect them via connecting wires according to conventional techniques.

FIG. 5 shows a cross-sectional view of a module with a three-dimensional structure fabricated by pressed assembly according to one variant of the invention. In this module, the isolation of the devices is achieved by deep trenches TP. A dielectric layer is deposited on the top surface of the substrates close to said trenches; the source (for N transistors) or drain (for P transistors) metallization layer lies on top of this dielectric layer and, for this reason, is raised with respect to the active surface of the chip. The electrical contacts between the free terminals of the transistors and the output terminals of the module are formed within these raised peripheral metallizations.

The simple observation of FIGS. 4A, 4B and 5 allows some of the advantages afforded by the three-dimensional assembly of the modules of the invention to be understood.

The first is represented by the simplification and the enhanced reliability of the connection systems, thanks to the elimination of the connecting wires and their replacement by metallization layers.

The very compact interconnection geometry also has important advantages from the electromagnetic point of view.

It enables the inductance of the “switching meshes”, formed by the positive and negative power supply lines and the various bridge arms, generating radiated interference (together with “inductive voltage spikes” during the switching, which necessitates an over-sizing of the components).

Furthermore, the shielding provided by the elements BV+ and BV−, forming the outside surfaces of the module and held at constant potentials, allows the interference conducted through the spurious capacitances to be minimized. This in turn allows the constraints on the common mode filtering, which contributes to a very significant extent to the size and to the cost of power converters, to be reduced.

The three-dimensional assembly also has advantages from the thermal point of view. This is because the elements BV+ and BV− can be attached to heat radiators; furthermore, if the element BV− is at ground potential, it is unnecessary for the radiator to be electrically isolated, which isolation would unavoidably reduce the thermal conductivity. In addition, the output terminals themselves can be used as heat sinks.

The principle of three-dimensional assembly, and the advantages that are associated with it, have already been disclosed, in applications using discrete components, in the following articles:

E. Vagnon, P. O. Jeannin, Y. Avenas, J. C. Crebier, K. Guepratte, “A Busbar Like Power Module Based On 3D Chip On Chip Hybrid Integration” 2th Annual IEEE Applied Power Electronics Conference and Exposition APEC 2009, 15-19 Feb. 2009, Pages 2072-2078; and

E. Vagnon, J.-C. Crebier, Y. Avenas, P.-O. Jeannin “Study and realization of a low-force 3D press-pack power module” IEEE Power Electronics Specialists Conference 2008, PESC 2008, 15-19 Jun. 2008, Pages 1048-1054.

However, the three-dimensional assembly of conventional multi-phase converters, composed of discrete transistors, is very difficult to achieve. The dual-chip structure of the invention, on the other hand, is very naturally suited to three-dimensional assembly.

As explained above, the bridge arms of a power module according to the invention can be of the complementary type (one switch of the N type and one of the P type) or otherwise (two switches of the same type, generally N). The use of a complementary structure is unusual in power electronics owing to the sub-optimal performance of p-type devices; consequently, its advantages and drawbacks deserve to be considered in greater detail.

A P-MOSFET exhibits losses in the conducting state which are 2-3 times higher than those of an equivalent N-MOSFET. However, it is possible to reduce the losses of the P-MOSFET by simply increasing its surface area, whereas that of the associated N-MOSFET remains unchanged. This does of course imply the use of a larger surface area of silicon with respect to a module having equivalent performance parameters and based only on N-MOS devices. But, this increase in surface area can be compensated by the reduction in surface area made possible by monolithic integration, and also by the simplification of the common-mode filtering resulting from the superior electromagnetic properties of the three-dimensional assembly (see hereinabove). The excellent thermal properties of the three-dimensional assembly also contribute to improving the performance of the devices, thus reducing the penalty associated with the use of p-type devices.

The fact that the N transistors of a module with a complementary structure are smaller than the corresponding P transistors allows the space remaining on the N-type chip to be used to integrate the control electronics for the bridge arms. This results in an optimal use of the available space.

In the case of bipolar components (diodes, BJTs, IGBTs), the penalty associated with the use of p-type devices is even smaller than for unipolar components (essentially MOSFETs).

Although p-type devices are unfavorable in terms of losses, the use of a complementary structure has a considerable advantage as far as the control of the bridge arm is concerned, as illustrated in FIGS. 6A and 6B. The reason for this is that when the same signal is applied to the gate of the two transistors, respectively of the N and P type, one goes into its conducting state while the other is in its off state. Thus, a single control circuit Cde allows the two transistors to be driven. More to the point, there is no case in which both transistors are in danger of being in their conducting state at the same time and causing a short-circuit.

In FIG. 6A, the references PS+ and PS− indicate the power supply circuits for the control or close-control circuit Cde. In FIG. 6B, t indicates time, V_{GSth+} and V_{GSth-} the threshold voltages of the N and P transistor, respectively, assumed to be substantially equal in absolute value but of opposite signs. The meanings of V_{Cde}, V_{GD}, I_{DSn} and I_{DSp} is clearly apparent from FIG. 6A.

FIGS. 7A to 7D illustrate one particular advantageous embodiment of the invention, characterized by a “coaxial” structure.

FIG. 7A shows the circuit diagram of a bridge arm comprising two transistors and their associated antiparallel diodes, and its decomposition into two switching cells CC1, CC2. Each of said switching cells CC1, CC2 is formed by a transistor and by the antiparallel diode of the other transistor. In the first switching cell CC1, the transistor T is connected between a supply line at a positive voltage, BV+, and an output terminal BS corresponding to the mid-point of the bridge arms, whereas the diode D is connected between said output terminal BS and a supply line at a negative voltage, BV−. Conversely, in the second cell CC2, the diode is connected between BV+ and BS and the transistor between BS and BV−.

An inductive load, modeled by an ideal current source, is connected between the output terminal BS and the negative voltage supply line BV−.

FIG. 7B shows the switching cell CC1 on its own. Indeed, the coaxial structure in FIGS. 7C, 7D only concerns one switching cell, and not a complete bridge arm. A bridge arm, or a more complex circuit, can be formed by connecting together two or more switching cells with a coaxial structure.

FIG. 7C shows a circuit diagram obtained by duplicating the cell in FIG. 7B in a symmetrical fashion with respect to the line BV−; there are now two positive power supply lines BV+′ and BV+″, together with two output terminals BS′ and BS″. The circuit in FIG. 7C is entirely equivalent to that in FIG. 7B, aside from the duplication of its components (T′, T″; D′, D″); it should especially not be confused with a complete bridge arm. In FIG. 7C, arrows indicate the direction in which the electrical current flows in each line; the lines comprising two arrows have a higher current flowing in them than the lines comprising a single arrow. The various lines form meshes, within which currents flow that are generated by the magnetic fields whose orientation is illustrated in the figure.

Lastly, FIG. 7D shows a cross-sectional view of a real embodiment of the circuit in FIG. 7C in the form of a three-dimensional assembly of chips exhibiting a functional symmetry with respect to a plane parallel to the chips composing it. In this assembly, each semiconductor component is formed, using vertical technology, on an independent chip; these chips are then superposed and the electrical interconnections formed by metallization layers corresponding to the lines BV+′ and BV+″, BS′ and BS″. Furthermore, the layers intended to be held at the same potential may be connected together on the sides (this is not essential). The end result is a “coaxial” structure, all the active elements of which are enclosed within a conducting envelope held at the (constant) positive supply potential. It will be understood that this is an excellent structure from the point of view of the electromagnetic compatibility thanks to the almost perfect confinement of the variable potentials that it provides.

A complete bridge arm may be obtained by disposing end-to-end two coaxial switching cells whose output terminals are mutually shared.

The use of MOSFETs or IGBTs equipped with an integrated freewheeling diode allows a complete bridge arm to be formed by means of a single coaxial structure. This is illustrated in FIGS. 11A and 11B that show, only by way of example, a stack of four identical N-MOSFETs (Tⁱ, Tⁱⁱ, Tⁱⁱⁱ, T^{iv}), exhibiting a plane of symmetry. During a first phase of operation, the transistors Tⁱⁱ and Tⁱⁱⁱ are driven in such a manner as to conduct the current, whereas the transistors Tⁱ and T^{iv} are turned off, for example by short-circuiting their gate and their source by means of a close-control circuit not shown. The line BS′/BS″ is therefore connected to the positive power supply BV′+/BV″+. During a second phase of operation, it is the transistors Tⁱ and T^{iv} that conduct, connecting BS to BV−, whereas Tⁱⁱ and Tⁱⁱⁱ are turned off. Therefore, a bridge arm operation is achieved.

Between two phases of operation, there is a short period during which all the transistors are turned off: this avoids any risk of short-circuit between BV′+, BV″+and BV−. It is now assumed that the line BS′/BS″ powers an inductive load: there should not therefore be any abrupt interruption of current. The body diodes of the MOSFETs intervene at this point, acting as freewheeling diodes in order to allow the current to flow despite the non-conducting state of the transistors. Thus, for example, between the first and the second phase of operation, the body diodes of Tⁱ and T^{iv} will start to conduct in order to allow the inductive load to discharge itself.

The MOSFET with a vertical structure naturally possesses a body diode designed to operate as a freewheeling diode; in other components, such as the IGBT, such a diode can be purposely co-integrated.

It can be noted in FIG. 11B that the lines BS′/BS″, BV′+/BV″+ and BV− are not fabricated in the form of metallization layers, but of metal sheets or plates. This variant embodiment may be applied to any coaxial structure whether it is forming one switching cell (FIG. 7C) or a complete bridge arm (FIG. 11A).

As shown in FIG. 12, the sheets forming the lines BV′+/BV″+, and potentially also BS′/BS″, can have an overlap with a sliding engagement in such a manner as to close the coaxial structure on its sides.

In the case of FIGS. 11B and 12, the assembly is held by clamping by means of an external force F which is exerted on the outside sheets BV′+/BV″+.

In the case of FIG. 13, the positive power supply is provided by a closed housing (at least on four of its six faces, if a parallelepiped shape is considered) BV+. The sheets BS′/BS″ again have a structure with sliding engagement; the same goes for the sheets BV′−/BV″−, between which a spring R (or a block of elastic material) is located exerting a separating force which presses the assembly from the inside against the internal surface of the housing BV+. A reversed structure, having the positive power supply on the inside and the negative power supply on the outside, is also possible.

The coaxial structure can be applied to the fabrication of power circuits comprising a plurality of parallel bridge arms. It is possible for example to fabricate a coaxial stack of chips integrating a plurality of components having a “free” terminal and a terminal with a common potential. In this way, each coaxial structure formed by a stack of chips exhibiting a functional symmetry with respect to a plane parallel to said chips constitutes a set of switching cells, or even of complete bridge arms. A power module according to the first or the second subject of the invention can thus be implemented.

As a variant, a discrete construction may be chosen.

FIG. 14A shows the circuit diagram of a bridge arm using discrete components (IGBTs) obtained by associating two switching cells of the type illustrated in FIG. 7C. FIG. 14B shows its physical embodiment, in the form of two stacks of chips sharing the same conducting sheets forming the lines BV′+/BV″+, BS′/BS″ and BV−. If the thickness of the chips of the diodes (D′₁, D″₁, D′₂, D″₂) and of the transistors (T′₁, T″₁, T′₂, T″₂) are different, separate sheets must be used for the lines BS′/BS″ of the various stacks, flexible contacts being used to connect them together.

FIG. 15A shows the physical embodiment of a three-phase inverter obtained using three stacks of the type in FIG. 11B sharing the same sheets BV′+/BV″+ and BV− (the output lines BS′/BS″ must of course be independent from one another). The sheet BV− should preferably comprise openings O₁, O₂, as illustrated in FIG. 15B, in order to allow the closing of the magnetic field lines and to avoid any magnetic coupling between the bridge arms.

As has been explained above, the terminations of the “mesa” type or the deep trenches allow the fabrication of components with symmetrical voltage blocking. Thus, the main obstacle to the fabrication of circuits comprising a plurality of current switch (or inverter) arms is lifted.

FIG. 10A shows the circuit diagram of a circuit of this type based on the use of complementary IGBTs. As FIG. 9 shows, the IGBT naturally possesses a P-N junction on its back face which forms the series diode required for a current switch arm. These components are particularly well adapted to high-voltage applications (100 V or more) for which the voltage drop across the terminals of this diode is negligible.

In the circuit in FIG. 10A, the emitters of the IGBTs on the same arm are connected to the same point (the output terminal); consequently, the control signals applied to the bases of these transistors are set to the same voltage level, a fact which allows the close-control circuits for each switching arm to be mutually shared.

The circuit in FIG. 10B differs from that in FIG. 10A in that the “upper chip” (connected to the positive power supply) integrates the P-type IGBT and the “lower chip” (connected to the negative power supply) integrates those of the N type. The emitters of the transistors of the same chip are connected to the respective power supplies; this allows the close-control circuits on each chip to be mutually shared.

The circuit in FIG. 10C only uses transistors of the higher performance N type. The drawback is that no mutual sharing of the close-control circuits is possible for the upper chip.

A circuit using only circuits of the P type may also be constructed, but it is not of any particular interest.

According to the invention, the circuits in FIGS. 10A, 10B and 10C are fabricated using dual-chip technology, and preferably in a sandwich structure.

The coaxial structure can also be applied to switching cells based on components that are bidirectional in voltage, in order to produce the current switches. FIG. 17 shows the circuit diagram of such a cell.

The topologies in FIGS. 10A, 10B and 10C can also be implemented using MOSFETs. The series diode can be of the Schottky type, fabricated by simply acting on the characteristics of the drain electrical contact. A structure with entirely unipolar operation, hence high-speed, is thus obtained with a small voltage drop across the terminals of the diode. Such a circuit is particularly suited to low- and medium-voltage applications (less than 100 V) and/or high-frequency applications (250 kHz or more). The fabrication of integrated current switches using dual-chip technology with integrated Schottky diodes requires chips using a thick metallization layer as an element providing both the structural integrity and an electrical connection between the switches (see the example in FIG. 3). The use of a substrate made of degenerated semiconductor (as in the example in FIG. 2) is indeed incompatible with the formation of a Schottky contact.

An example of a multiphase current switch using MOSFETs according to one embodiment of the invention is illustrated in FIG. 10D. Its topology corresponds to that in FIG. 10B, which is probably the most advantageous in the majority of cases. Other topologies are also possible.

The switches or current inverters have the interesting property of making possible the self-powering of the close-control circuits. In other words, the power supply for these circuits can come directly from positive and negative supplies of the switch.

Document EP 1 387 474 describes a circuit enabling the self-powering of the close control of a power transistor.

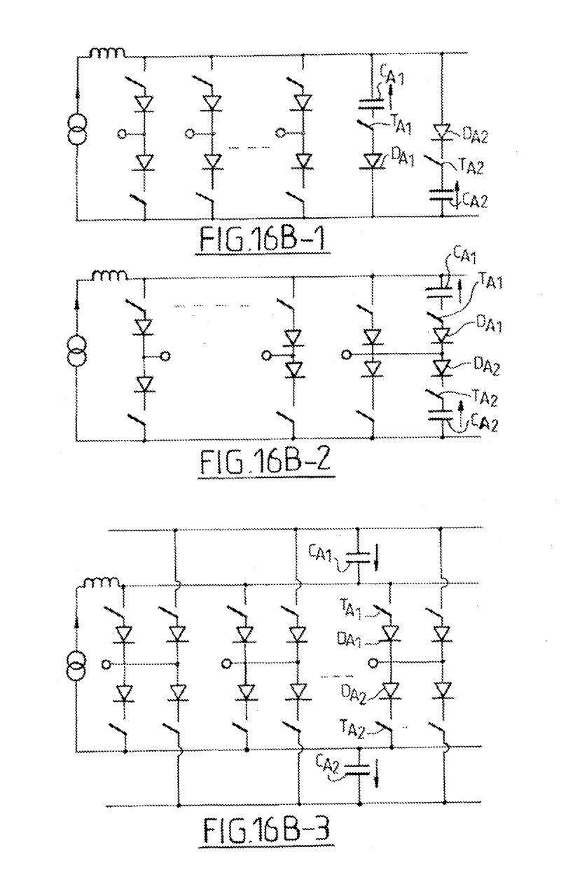

FIG. 16A shows how this self-powering can be carried out in the case of the circuit in FIG. 10A (complementary structure, “N” transistor connected to the positive power supply and “P” transistor connected to the negative power supply). Each switch arm is equipped with two auxiliary transistors T_{A1}, T_{A2}, two auxiliary diodes connected in series D_{A1}, D_{A2} to the respective transistors and two capacitors C_{A1}, C_{A2} connected in series with the diodes and transistors. Across the terminals of the capacitors C_{A1}, a voltage V_{A1} can be obtained that is positive with respect to the voltage of the mid-point V_{M} to which the emitters or sources of the transistors of the current switch arm are connected. This voltage allows the (positive) signal to be generated that is to be applied to the base or gate of the “upper” transistor, of the N type, of said arm in order to activate it. Similarly, across the terminals of the capacitors C_{A2}, a voltage V_{A2} can be obtained that is negative with respect to the voltage of the mid-point V_{M}. This voltage allows the (negative) signal to be generated that is to be applied to the base or gate of the “lower” transistor, of the P type, of said arm in order to activate it.

The auxiliary diodes and transistors are readily integrated into the power chips forming the multiphase current switch. These components can furthermore be small as they do not have to handle high powers.

FIG. 16B shows how this self-powering can be achieved in the case of the circuit in FIG. 10B (complementary structure, “P” transistor connected to the positive power supply and “N” transistor connected to the negative power supply); in this case, a single self-powering circuit comprising two auxiliary transistors T_{A1}, T_{A2}, two auxiliary diodes connected in series D_{A1}, D_{A2} with the respective transistors and two capacitors C_{A1}, C_{A2} connected in series with the diodes and transistors. Across the terminals of the capacitors C_{A1}, a voltage V_{A1} can be obtained that is negative with respect to the positive power supply V+ to which the emitters or sources of the transistors of the upper half of the current switch are connected. This voltage allows the (negative) signal to be generated that is to be applied to the base or gate of the “upper” transistors, of the P type, in order to activate them. Similarly, across the terminals of the capacitors C_{A2}, a voltage V_{A2} can be obtained that is positive with respect to the negative power supply V− to which the emitters or sources of the transistors of the lower half of the current switch are connected. This voltage allows the (positive) signal to be generated that is to be applied to the base or gate of the “lowers” transistors, of the N type, in order to activate them.

As in the case in FIG. 16A, the auxiliary diodes and transistors are readily integrated into the power chips forming the multiphase current switch.

FIGS. 16B-1, 16B-2 and 16B-3 show three “degraded” variants of the circuit in FIG. 16B that are more difficult to integrate. In the case in FIG. 16B-3, auxiliary diodes and transistors are connected in parallel with each switch arm.

Finally, FIG. 16C shows how the self-powering can be achieved in the case of the circuit in FIG. 10C (non-complementary structure using exclusively N transistors). The self-powering circuit is intermediate between those in FIGS. 16A and 16B-2 and its operation is easily understood.

As a variant, the self-powering of the close-control circuits of the lower part of the switch can be mutually shared.

1. A power electronic module comprising a plurality of bridge arms connected in parallel and a plurality of output terminals connected to the mid-points of said bridge arms, comprising at least two semiconductor chips, each of said chips monolithically integrating a plurality of solid-state switches fabricated using vertical technology whose active and voltage blocking regions are electrically isolated from one another, each switch of one chip being connected to a respective switch of another chip in such a manner as to form one said bridge arm, characterized in that each of said chips comprises a conducting element extending over one of its faces and ensuring both its structural integrity and an electrical connection between all the switches of the chip.

2. The power electronic module as claimed in claim 1, in which each solid-state switch possesses at least a first and a second electrical contact terminal, the first terminals of the switches on the same chip being connected to said conducting element so as to be held at a common potential and the second terminals, called free terminals, being connected to said output terminals of the module.

3. The power electronic module as claimed in claim 2, in which at least one of said chips is fabricated on an N-type substrate and at least another is fabricated on a P-type substrate, the two switches forming each bridge arm being of the complementary type.

4. The power electronic module as claimed in claim 3, in which the P-type switches have an active surface that is larger than that of the N complementary transistors so as to compensate for the tiniest amount of conductivity of their active regions.

5. The power electronic module as claimed in claim 2, in which said chips are fabricated on substrates having a doping of the same type and comprise switches also of the same type.

6. The power electronic module as claimed in claim 2, comprising two semiconductor chips superposed in such a manner that the free terminals of the switches of the first chip are disposed facing the corresponding free terminals of the switches of the second chip.

7. The power electronic module as claimed in claim 2, comprising a first and a second set of switching cells connected together by power supply lines and common output terminals in such a manner as to form said plurality of bridge arms connected in parallel, each set of switching cells being formed by a stack of semiconductor chips and exhibiting a functional symmetry with respect to a plane parallel to the chips forming it, each of said chips monolithically integrating a plurality of solid-state switches fabricated using vertical technology having active and voltage blocking regions electrically isolated from one another, first terminals connected to said conducting element so as to be held at a common potential and second terminals, called free terminals, connected to said output terminals of the module.

8. The power electronic module as claimed in claim 2, in which at least one of said chips is composed of a degenerated semiconductor substrate (S₁) on which a epitaxial layer (S₂) is deposited into which said switches are integrated, said degenerated semiconductor substrate forming said conducting element ensuring both the mechanical robustness of the chip and the electrical connection between the first terminals of said switches.

9. The power electronic module as claimed in claim 2, in which at least one of said chips is composed of a thinned semiconductor substrate (S′) into which said switches are integrated, on one face of which is deposited a layer of conducting material (M′) forming said conducting element ensuring both the mechanical robustness of the chip and the electrical connection between the first terminals of said switches.

10. The power electronic module as claimed in claim 1 in which the switches integrated into at least one of said chips are controlled switches, such as transistors, each comprising a control terminal.

11. The power electronic module as claimed in claim 10, in which at least one of said chips also integrates control circuits for said switches.

12. The power electronic module as claimed in claim 10, in which the two switches forming each bridge arm are of the complementary type and have a common control terminal.

13. The power electronic module as claimed in claim 1, in which the active and voltage blocking regions of the switches integrated into the same chip are physically separated by hollow trenches or furrows after the fabrication of the switches.

14. The power electronic module as claimed in claim 13, in which the edges of said active and voltage blocking regions are beveled and passivated by a dielectric coating thus forming a voltage termination of the “mesa” type.

15. The power electronic module as claimed in claim 13, in which the active and voltage blocking regions of the switches integrated into the same chip are separated by substantially vertical trenches filled with a dielectric material.

16. The power electronic module comprising a plurality of bridge arms connected in parallel and a plurality of output terminals connected to the mid-points of said bridge arms, comprising at least two semiconductor chips, each of said chips monolithically integrating a plurality of solid-state switches fabricated using vertical technology whose active and voltage blocking regions are electrically isolated from one another, each switch of one chip being connected to a respective switch of another chip in such a manner as to form one said bridge arm, characterized in that said switches exhibit symmetrical voltage blocking, subject to which said bridge arms can operate as current inverter arms.

17. The power electronic module as claimed in claim 16, in which each solid-state switch possesses at least a first and a second electrical contact terminal, the first terminals of the switches of the same chip being connected to a conducting element so as to be held at a common potential and the second terminals, called free terminals, being connected to said output terminals of the module.

18. The power electronic module as claimed in claim 17, in which at least one of said chips is fabricated on an N-type substrate and at least another is fabricated on a P-type substrate, the two switches forming each bridge arm being of the complementary type.

19. The power electronic module as claimed in claim 18, in which the P-type switches have an active surface that is greater than that of the N complementary transistors so as to compensate for the tiniest amount of conductivity of their active regions.

20. The power electronic module as claimed in claim 17, in which said chips are fabricated on substrates having a doping of the same type and comprise switches also of the same type.

21. The power electronic module as claimed in claim 17, comprising two semiconductor chips superposed in such a manner that the free terminals of the switches of the first chip are disposed facing the corresponding free terminals of the switches of the second chip.

22. The power electronic module as claimed in claim 17, comprising a first and a second set of switching cells connected together by power supply lines and common output terminals in such a manner as to form said plurality of bridge arms connected in parallel, each set of switching cells being formed by a stack of semiconductor chips and exhibiting a functional symmetry with respect to a plane parallel to the chips forming it, each of said chips monolithically integrating a plurality of solid-state switches fabricated using vertical technology having active and voltage blocking regions electrically isolated from one another, first terminals connected to said conducting element so as to be held at a common potential and second terminals, called free terminals, connected to said output terminals of the module.

23. The power electronic module as claimed in claim 17, in which at least one of said chips is composed of a degenerated semiconductor substrate on which a epitaxial layer is deposited into which said switches are integrated, said degenerated semiconductor substrate forming said conducting element ensuring both the mechanical robustness of the chip and the electrical connection between the first terminals of said switches.

24. The power electronic module as claimed in claim 17, in which at least one of said chips is composed of a thinned semiconductor substrate into which said switches are integrated, on one face of which is deposited a layer of conducting material forming said conducting element ensuring both the mechanical robustness of the chip and the electrical connection between the first terminals of said switches.

25. The power electronic module as claimed in claim 16, in which the switches integrated into at least one of said chips are controlled switches, such as transistors, each comprising a control terminal.

26. The power electronic module as claimed in claim 25, in which at least one of said chips also integrates control circuits for said switches.

27. The power electronic module as claimed in claim 25, in which the two switches forming each bridge arm are of the complementary type and have a common control terminal.

28. The power electronic module as claimed in claim 16, in which the active and voltage blocking regions of the switches integrated into the same chip are physically separated by hollow trenches or furrows after the fabrication of the switches.

29. The power electronic module as claimed in claim 28, in which the edges of said active and voltage blocking regions are beveled and passivated by a dielectric coating thus forming a voltage termination of the “mesa” type.

30. The power electronic module as claimed in claim 28, in which the active and voltage blocking regions of the switches integrated into the same chip are separated by substantially vertical trenches filled with a dielectric material.

31. The power electronic module as claimed in claim 16, comprising close-control circuits for said solid-state switches with symmetrical voltage blocking, together with means for powering said close-control circuits from a positive supply line and from a negative supply line between which said module is connected.

32. A power electronic module comprising a stack of four semiconductor chips and five conducting layers arranged alternately, two of said semiconductor chips integrating with vertical technology at least one respective controlled switch, whereas each of the two other semiconductor chips integrate, also using vertical technology, at least one respective diode, said controlled switches and said diodes being configured in a functionally symmetrical manner with respect to a central conducting layer and in such a manner as to form a switching cell.

33. The power electronic module as claimed in claim 32 in which the conducting layers arranged on either side of said central conducting layer are electrically connected together in pairs, in such a manner as to form a coaxial structure in which said controlled switches and said diodes are enclosed inside a conducting envelope.

34. The power electronic module as claimed in claim 32 in which said controlled switches are transistors.

35. A bridge arm formed by the association of two power electronic modules as claimed in claim 32.

36. The power electronic module as claimed in claim 32 in which each of said chips integrates a plurality of controlled switches or diodes, respectively, in such a manner as to form a plurality of switching cells in parallel.

37. A set of bridge arms connected in parallel formed by the association of two power electronic modules as claimed in claim 36.

38. The power electronic module as claimed in claim 32 in which each of said four semiconductor chips integrates at least one transistor and one antiparallel diode, subject to which said module can operate as a complete inverter arm.

39. The power electronic module as claimed in claim 32, in which said conducting layers are metal sheets, the stack being held by mechanical pressing.

40. The power electronic module as claimed in claim 39 in which at least two of said sheets, arranged symmetrically with respect to the sheet forming said central layer, are electrically connected together by means of a sliding contact.

41. A set of bridge arms connected in parallel formed by the association of a plurality of power electronic modules as claimed in claim 39, at least both the outside conducting sheets being common to all the stacks of chips.
